(19) United States
(12) Patent Application Publication
(10) Pub. No.: US 2013/0049024 A1
(43) Pub. Date: Feb. 28, 2013

(54) ORGANIC ELECTROLUMINESCENCE DISPLAY DEVICE

(71) Applicants: Sung Hoon Choi, Daegu (KR); Sang Dae Kim, Daegu (KR); Byung Soo Kim, Seoul (KR); Tae Il Kum, Daegu (KR); Young Dock Cho, Busan (KR); Sang Kyoung Moon, Ulsan (KR)

(72) Inventors: Sung Hoon Choi, Daegu (KR); Sang Dae Kim, Daegu (KR); Byung Soo Kim, Seoul (KR); Tae Il Kum, Daegu (KR); Young Dock Cho, Busan (KR); Sang Kyoung Moon, Ulsan (KR)

(21) Appl. No.: 13/337,988

(22) Filed: Dec. 27, 2011

(30) Foreign Application Priority Data
Aug. 26, 2011 (KR) 10-2011-0086091

(51) Int. Cl. H01L 51/50

(52) U.S. Cl. 257/88; 257/E51.018

(57) ABSTRACT

An OLED device adapted to enhance reliability and light-emitting efficiency is disclosed. The disclosed OLED device includes: a first electrode; an emission layer formed on the first electrode; a second electrode formed on the emission layer; and an electron injection layer disposed on the emission layer, configure to be in contact with the second electrode and in a single layer which is formed from a mixture of an inorganic compound and a metal material with a low work function.

This application claims the priority and the benefit under 35 U.S.C. §119(a) on Korean Patent Application No. 10-2011-0086091, filed on Aug. 26, 2011, the entire contents of which are hereby incorporated by reference.

### BACKGROUND

1. Field of the Invention

This disclosure relates to an organic electro luminescence display (OLED) device, and more particularly to an OLED device adapted to enhance its reliability and light emitting efficiency.

2. Discussion of the Related Art

OLED devices are one of flat panel display devices that display images by controlling the light emitting quantity of an organic light emission layer. Such OLED devices can have reduced weight and volume which are well known as disadvantages of cathode ray tubes (CRTs). In view of this point, the OLED devices are recently spotlighted in a display field.

The OLED devices are self-illuminating display devices using a light emission layer between electrodes. In other words, the OLED devices do not require a backlight unit for applying light, unlike LCD (liquid crystal display) devices. As such, the OLED devices are capable of becoming thinner.

In order to display images, the OLED device includes a plurality of pixels arranged in a matrix shape. Each of the pixels is configured with 3 colored sub-pixels which are colored red, green and blue, respectively.

Each of the sub-pixels includes an organic electro-luminescent cell and a cell driver. The cell driver is used to independently drive the respective organic electro-luminescent cell.

Such a cell driver includes at least two thin film transistors and a single storage capacitor, which are connected between a gate line, a data line and a common power-supply line, in order to drive the respective organic electro-luminescent cell. The gate line is used to transfer a scan signal, the data line is used to transfer an image signal, and the common power-supply line is used to transfer a common power-supply signal.

The organic electro-luminescent cell includes a pixel electrode connected to the respective cell driver, an organic light emission layer on the pixel electrode, and a cathode on the organic light emission layer. Meanwhile, an OLED panel can be completed by combining an upper substrate and a lower substrate on which the thin film transistors and the organic electro-luminescent cells are formed.

The organic light emission layer is ordinarily structured to include a hole injection layer, a hole transportation layer, an emission layer, an electron transportation layer, and an electron injection layer. The electron injection layer is mainly formed from an inorganic compound which allows for easy electron injection. The ordinary organic light emission layer can provide a superior light-emitting efficiency as the electron injection layer is formed from an inorganic compound.

However, the inorganic electron injection layer deteriorates interfacial characteristics with the cathode. Due to this, a dark spot can be generated on a pixel-by-pixel basis. Such a dark spot causes reliability to deteriorate.

### BRIEF SUMMARY

An OLED device includes: a first electrode; an emission layer formed on the first electrode; a second electrode formed on the emission layer; and an electron injection layer disposed on the emission layer, configure to be in contact with the second electrode and in a single layer which is formed from a mixture of an inorganic compound and a metal material with a low work function.

Other systems, methods, features and advantages will be, or will become, apparent to one with skill in the art upon examination of the following figures and detailed description. It is intended that all such additional systems, methods, features and advantages be included within this description, be within the scope of the invention, and be protected by the following claims. Nothing in this section should be taken as a limitation on those claims. Further aspects and advantages are discussed below in conjunction with the embodiments. It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the embodiments and are incorporated in and constitute a part of this application, illustrate embodiment(s) of the invention and together with the description serve to explain the disclosure. In the drawings:

FIG. 1 is a circuit diagram schematically showing a pixel within an OLED device according to an embodiment of the present disclosure;

FIG. 2 is a cross-sectional view schematically showing an OLED device according to an embodiment of the present disclosure;

FIG. 3 is a cross-sectional view showing in detail the OLED element in FIG. 2;

FIG. 4 is a graph diagram representing light-absorption ratios of magnesium Mg and ytterbium Yb, which can be included in electron injection layer according to an embodiment of the present disclosure, with respect to a wave length of light; and

FIG. 5 is a table representing drive voltages, current efficiencies, and power efficiencies of the OLED device which are varied along examples of an electron injection layer according to an embodiment of the present disclosure.

### DETAILED DESCRIPTION OF THE DRAWINGS AND THE PRESENTLY PREFERRED EMBODIMENTS

Reference will now be made in detail to the embodiments of the present disclosure, examples of which are illustrated in the accompanying drawings. These embodiments introduced hereinafter are provided as examples in order to convey their spirits to the ordinary skilled person in the art. Therefore, these embodiments might be embodied in a different shape, so are not limited to these embodiments described here.

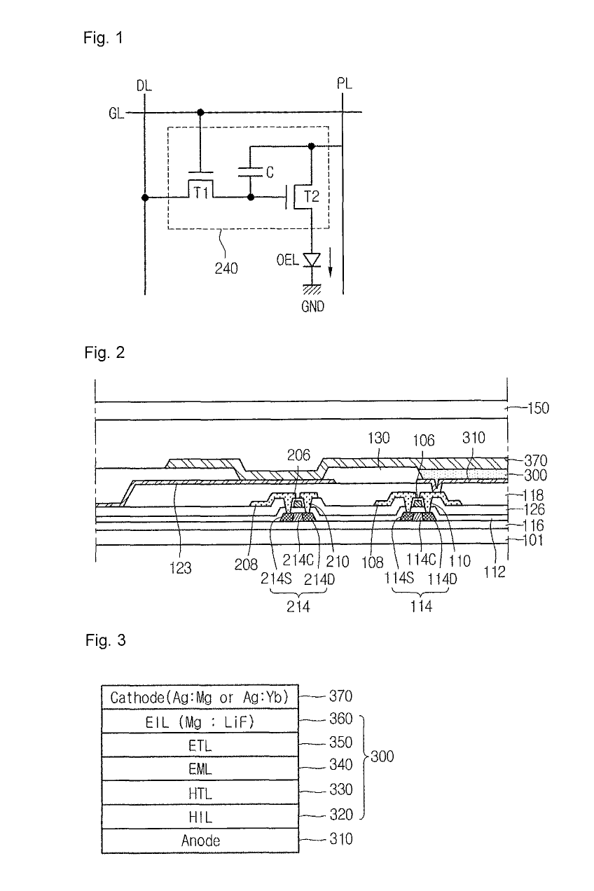

FIG. 1 is a circuit diagram schematically showing a pixel within an OLED device according to an embodiment of the present disclosure. FIG. 2 is a cross-sectional view schematically showing an OLED device according to an embodiment of the present disclosure. FIG. 3 is a cross-sectional view showing in detail the OLED element in FIG. 2;

The OLED device includes upper and lower substrates combined by a sealant in such a manner so as to be opposite each other. Each of pixels within the OLED device includes a cell driver 240 connected to a gate line GL, a data line DL and a power-supply line PL, and an organic electro-luminescent cell OEL connected to the cell driver 240 and a basal power line GND, as shown in FIG. 1.

The cell driver 240 includes: a switching thin-film transistor T1 connected to the gate line GL and the data line DL; a driving thin-film transistor T2 connected between the switching thin-film transistor T1, the power-supply line PL and an anode of the organic electro-luminescent cell OEL; and a storage capacitor C connected between a drain electrode of the switching thin-film transistor T1 and the power-supply line PL.

The switching thin-film transistor T1 includes a gate electrode connected to the gate line GL, a source electrode connected to the data line DL, and the drain electrode connected to the storage capacitor C and a gate electrode of the driving thin-film transistor T2. The driving thin-film transistor T2 includes a source electrode connected to the power-supply line PL, and a drain electrode connected to a pixel electrode which is used as an anode of the organic electro-luminescent cell OEL. The storage capacitor C is connected between the gate electrode of the driving thin-film transistor T2 and the power-supply line PL.

When a scan pulse is applied through the gate line GL, the switching thin-film transistor T1 is turned-on and transfers a data signal on the data line DL to the storage capacitor C and the gate electrode of the driving thin-film transistor T2. The driving thin-film transistor T2 replies to the data signal applied to its gate electrode and controls an electric current applied from the power-supply line PL to the organic electro-luminescent cell OEL, thereby adjusting a light emitting quantity of the organic electro-luminescent cell OEL. Also, the driving thin-film transistor T2 continues to supply the organic electro-luminescent cell OEL with a constant electric current corresponding to a charged voltage of the storage capacitor C and enables the organic electro-luminescent cell OEL to continuously emit light until another data signal of the next frame is applied, even though the switching thin-film transistor T1 is turned-off.

The upper substrate included in the OLED device with the above-mentioned structure can be formed from a transparent or opaque material. The upper substrate is used to encapsulate the above mentioned components of the OLED device.

The upper substrate formed from an opaque material is used to structure a top emission type OLED device which displays images in an upward direction. On the contrary, the upper substrate formed from a transparent material is used to structure a bottom emission type OLED device which displays images in a downward direction.

Referring to FIG. 2, the OLED device according to an embodiment of the present disclosure includes a driving thin-film transistor and a switching thin-film transistor which are used to configure a single pixel. The driving thin-film transistor includes: a buffer layer 116 and a gate insulation layer 112 stacked on a transparent insulation substrate 101; a first gate electrode 106 formed on the gate insulation layer 112; and an inter-layer insulation layer 126 formed on the gate insulation layer 112. The driving thin-film transistor further includes: a first source electrode 108 and a first drain electrodes 110 formed on the inter-layer insulation layer 126 around the first gate electrode 106; and a first active layer pattern 114 configured to form a channel between the first source electrode 108 and the first drain electrode 110 and connected to the first source electrode 108 and the first drain electrode 110 via contact holes which penetrate through the inter-layer insulation layer 126 and the gate insulation layer 112.

The first active layer pattern 114 is formed on the buffer layer 116 covering the insulation substrate 101. The first gate electrode 106 overlaps with a first channel region 114C of the first active layer pattern 114 with the gate insulation layer 112 interposed between it and the first active layer pattern 114. The first source electrode 108 and the first drain electrode 110 are in contact with a first source region 114S and a first drain region 114D, which are doped with an impurity, through the contact holes.

The OLED device according to an embodiment of the present disclosure further includes a planarization layer 118. The planarization layer 118 is formed on the inter-layer insulation layer 126 provided with the first source and drain electrodes 108 and 110.

Moreover, the OLED device according to an embodiment of the present disclosure includes a first electrode 310, a bank insulation layer 130, an organic light emission layer 300, and a second 370. The first electrode 310 is formed from a transparent conductive material and on the planarization layer 118. The first electrode 310 is electrically connected to the first drain electrode 110 via a contact hole which penetrates through the planarization layer 118. Such a first electrode can be defined as a pixel electrode. The bank insulation layer 130 is formed on the planarization layer 118 and edges of the first electrode 310 and configured to expose the first electrode 310 corresponding to a pixel region. The organic light emission layer 300 including an emission layer is formed on the exposed first electrode 310. The second electrode 370 is formed on the bank insulation layer 130 and the organic light emission layer 300.

The switching thin-film transistor includes: the buffer layer 116 and the gate insulation layer 112 stacked on the transparent insulation substrate 101; a second gate electrode 206 branched from a gate line (not shown) on the gate insulation layer 112; and the inter-layer insulation layer 126 formed on the gate insulation layer 112. The switching thin-film transistor further includes: a second source electrode 208 and a second drain electrode 210 formed on the inter-layer insulation layer 126 around the second gate electrode 206; and a second active layer pattern 214 configured to form a channel between the second source electrode 208 and the second drain electrode 210 and connected to the second source electrode 208 and the second drain electrode 210 via contact holes which penetrate through the inter-layer insulation layer 126 and the gate insulation layer 112.

The second active layer pattern 214 is formed on the buffer layer 116 covering the insulation substrate 101. The second gate electrode 206 overlaps with a second channel region 214C of the second active layer pattern 214 with the gate insulation layer 112 interposed between it and the second active layer pattern 214. The second source electrode 208 and the second drain electrode 210 are in contact with a second source region 214S and a second drain region 214D, which are doped with an impurity, through the contact holes. The planarization layer 118 is formed on the gate insulation layer 112.

Furthermore, the OLED device according to an embodiment of the present disclosure includes an auxiliary electrode 123 formed on the planarization layer 118. The auxiliary electrode 123 is formed from a transparent conductive material and used to transfer a basal power. The auxiliary electrode is partially exposed through an opening of the bank insulation layer 130. In other words, the bank insulation layer 130 is formed on the auxiliary electrode 123 and the planarization layer 118 except for a part of the auxiliary electrode 123. In accordance therewith, the second electrode 370 is also formed on the exposed auxiliary electrode as well as the bank insulation layer 130.

As shown in FIG. 3, the light emission layer 300 includes a hole injection layer (HIL) 320, a hole transportation layer (HTL) 330, the emission layer (EML) 340, an electron transportation layer (ETL) 350 and an electron injection layer (EIL) 360 sequentially stacked between the first and second electrodes 310 and 370. The first and second electrodes 310 and 370 are used as anode and cathode of the organic electro-luminescent cell OEL, respectively.

The first electrode 310 functions to provide holes to the light emission layer 300. Also, the first electrode 310 can be formed from a transparent conductive material in case the light emitted from the light emission layer 300 passes through the first electrode 310 and provides an image to users. For example, the first electrode 310 can be formed from one of indium tin oxide (ITO) and indium zinc oxide (IZO).

The light emission layer 300 can be formed from a host material and at least one material arbitrarily selected from dopant materials. The host material includes distyrylarylene (DSA), distyrylarylene (DSA) derivatives, distyrylbenzene (DSB), distyrylbenzene (DSB) derivatives, BAIq, Alq3 (tri(8-quinolynolactone)aluminum), CBP (4,4′-N,N′-dicarbazolephenyl-biphenyl), BCP, DCB and so on. The dopant materials can be used as fluorescent dopant materials. The dopant materials include DPVBi (4,4′-bis(2,2′-diphenyl vinyl)-1,1′-biphenyl), distyrylamine derivatives, phylene derivatives, pherylene derivatives, distyrylbiphenyl (DSBP) derivatives, 10-(1,3-benzothiazole-2-yl)-1,1,7,7-tetramethyl-2,3,6,7-tetrahydro-1H,5H,11H-pyrano(2,3-f)pyrido(3,2,1-ij)quinolyne-11-one (C545T), quinacridone derivatives, 4-(dicyanomethylene)-2-tertbutyl-6-(tetramethyljulolydyl-9-enyl)-4H-phyran (DCJTB), 4-dicyanomethyl-6-(p-dimethylaminostyryl)-4H-phyran (DCM) and so on.

The organic light emission layer 300 will now be described in detail. The hole injection layer (HIL) 320 forces the electric holes to be easily emitted from the first electrode 310 and applied toward the emission layer (EML) 340. To this end, the hole injection layer (HIL) 320 can be formed from a homo-material with a work function which has a small difference from that of the first electrode 310.

The hole transportation layer (HTL) 330 functions to prevent the transmission of energy from the emission layer 340 to the hole injection layer (HIL) 320. Also, the hole transportation layer 330 is used to transport the electric holes emitted from the first electrode 310 to the emission layer (EML) 340.

The second electrode 370 includes a material with a superior reflexibility. Such a second electrode 370 can become a single layer including silver Ag and one of magnesium Mg and ytterbium Yb.

The electron injection layer (EIL) 360 enables the electrons to be not only easily emitted from the second electrode 370 but also applied to the emission layer (EML) 340. The electron injection layer 360 can be formed from a mixture of an inorganic compound and a metal material.

Actually, the electron injection layer (EIL) 360 included in the OLED device of the present disclosure can become a single layer which is formed from a mixture of lithium fluoride LiF and one of magnesium Mg and ytterbium Yb. Lithium fluoride LiF forces the electrons to be easily injected. Both the magnesium Mg and ytterbium Yb can improve surface characteristics. Lithium fluoride and one of magnesium Mg and ytterbium Yb can be mixed in a ratio range of about 1:3 through about 3:1, in order to be used to form the electron injection layer (EIL) 360. Such an electron injection layer (EIL) 360 can be formed in a thickness range of about 10 Å about 50 Å.

TABLE 1

| | | Current efficiency | Power efficiency |
|---|---|---|---|
| EIL | Drive voltage (V) | (cd/A) | (lm/W) |
| LiF | 3.9 | 4.4 | 3.4 |
| Yb | 4.4 | 3.9 | 2.9 |
| Yb:LiF | 3.9 | 4.5 | 3.6 |

As seen from table 1, it is evident that the electron injection layer (EIL) 360 formed from the mixture of ytterbium Yb and an inorganic compound such as lithium fluoride LiF can not only enhance a light emitting efficiency but also improve surface characteristics of the second electrode 370. However, an electron injection layer (EIL) formed from only the inorganic compound of lithium fluoride LiF enhances a light emitting efficiency, but deteriorates surface characteristics of the second electrode 370. Meanwhile, another electron injection layer (EIL) formed from only ytterbium Yb improves the surface characteristics of the second electrode 370, but deteriorates a light emitting efficiency.

In this manner, the OLED device according to an embodiment of the present disclosure forces the electron injection layer (EIL) 360 to be formed from an inorganic compound, such as lithium fluoride, and one of magnesium Mg and ytterbium Yb. As such, the surface characteristics of the second electrode 370 are improved. Therefore, the OLED device can prevent the generation of a dark spot unlike the ordinary OLED device, and furthermore enhance the light emitting efficiency.

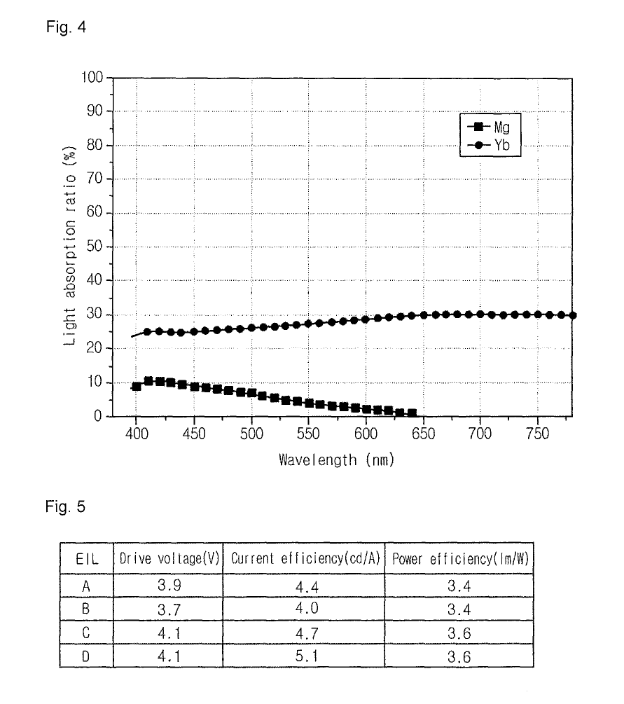

FIG. 4 is a graph diagram representing light-absorption ratios of Mg and Yb, which can be included in electron injection layer according to an embodiment of the present disclosure, with respect to a wave length of light. The light-absorption ratio data of FIG. 4 is obtained from a simulation.

As shown in FIG. 4, the light-absorption ratios of magnesium Mg and ytterbium Yb are no more than about 30 percent. More specifically, the light-absorption ratio of magnesium Mg is no more than about 10 percent, and the light-absorption ratio of ytterbium Yb is in a percent range of about 25˜30 percent.

The light absorption simulation is performed for magnesium and ytterbium layers using light in a wavelength range of 400˜800 nm. In this case, the magnesium and ytterbium layers are formed to each have a thickness of about 160 Å.

In accordance therewith, magnesium Mg and ytterbium Yb each have low work function and a low light-absorption ratio and can be used as a metal material which can be included in the electron injection layer.

Alternatively, the electron injection layer can be formed to include a metal with a work function of below 4.0 eV. As such, although the electron injection layer according to the present embodiment is explained to include one of magnesium Mg and ytterbium Yb, it is not limited to this. In other words, the electron injection layer can be formed to include lithium Li.

FIG. 5 is a table representing drive voltages, current efficiencies, and power efficiencies of the OLED device which are varied along examples of an electron injection layer according to an embodiment of the present disclosure.

As represented in the table of FIG. 5, the drive voltage, current efficiency and power efficiency of the OLED device can be varied along the thickness of the electron injection layer, which is formed from a mixture of an inorganic compound and a metal material, and/or a kind of metal material included in the mixture.

In the table of FIG. 5, “A” is an electron injection layer which is formed from a mixture of lithium fluoride LiF and ytterbium Yb in a thickness of about 10 Å. “B” is another electron injection layer which is formed from a mixture of lithium fluoride LiF and ytterbium Yb in a thickness of about 30 Å. “C” is still another electron injection layer which is formed from a mixture of lithium fluoride LiF and magnesium Mg in a thickness of about 10 Å. “D” is further still another electron injection layer which is formed from a mixture of lithium fluoride LiF and magnesium Mg in a thickness of about 30 Å.

The light emitting efficiency of the OLED device has a deviation according to the thickness of the electron injection layer. However, it is evident that the light emitting efficiency of the OLED device is greatly enhanced when magnesium Mg instead of ytterbium Yb is included in the mixture.

As described above, the OLED device according to an embodiment of the present disclosure includes the electron injection layer which is formed from a mixture of an inorganic compound (such as lithium fluoride LiF) and a metal material (such as magnesium Mg, ytterbium Yb and lithium Li) having a low work function and a superior interfacial characteristic with the second electrode and in a single layer structure. As such, the surface characteristics of the second electrode are improved. Therefore, the OLED device can prevent the generation of a dark spot unlike the ordinary OLED device, and can furthermore enhance the light emitting efficiency.

Although the present disclosure has been limitedly explained regarding only the embodiments described above, it should be understood by the ordinary skilled person in the art that the present disclosure is not limited to these embodiments, but rather that various changes or modifications thereof are possible without departing from the spirit of the present disclosure. Accordingly, the scope of the present disclosure shall be determined only by the appended claims and their equivalents.

1. An organic electro-luminescence display device comprising:
a first electrode;
an emission layer on the first electrode;
a second electrode on the emission layer; and
an electron injection layer disposed on the emission layer, in contact with the second electrode and in a single layer, which is formed from a mixture of an inorganic compound and a metal material with a low work function.

2. The organic electro-luminescence display device claimed as claim 1, wherein the inorganic compound of the electron injection layer includes lithium fluoride LiF.

3. The organic electro-luminescence display device claimed as claim 1, wherein the metal material of the electron injection layer includes one of magnesium Mg, ytterbium Yb and lithium Li.

4. The organic electro-luminescence display device claimed as claim 1, wherein the inorganic compound and the metal material are mixed in a ratio range of about 1:3 through about 3:1.

5. The organic electro-luminescence display device claimed as claim 1, wherein the electron injection layer has a thickness in a range of about 10 Å through about 50 Å.

6. The organic electro-luminescence display device claimed as claim 1, wherein a work function of the metal material is no more than 4.2 eV.

7. The organic electro-luminescence display device claimed as claim 1, wherein the second electrode is a cathode and a single layer which is formed from a mixture of aluminum and one of magnesium Mg and ytterbium Yb.

8. The organic electro-luminescence display device claimed as claim 1, wherein the first electrode is an anode and includes a transparent conductive material.
